(19) United States
(12) Patent Application Publication
(10) Pub. No.: US 2022/0346274 A1
(43) Pub. Date: Oct. 27, 2022

(54) HEAT DISSIPATION STRUCTURE AND MANUFACTURING METHOD THEREOF

(71) Applicant: TAIWAN MICROLOOPS CORP., New Taipei City (TW)

(72) Inventor: Chun-Hung LIN, New Taipei City (TW)

(21) Appl. No.: 17/240,521

(22) Filed: Apr. 26, 2021

(51) Int. Cl. H05K 7/20; F28D 15/04

(52) U.S. Cl. CPC H05K 7/20336; F28D 15/04

(57) ABSTRACT

The disclosure provides a heat dissipation structure and a manufacturing method thereof. The heat dissipation structure includes a heat pipe and multiple heat dissipation fins. The heat pipe has an outer annular wall with multiple conic annular grooves. A slant inner annular wall is disposed in each conic annular groove. Each heat dissipation fin has a through hole and a conic annular wall disposed on an outer edge of the through hole. The heat dissipation fins are adapted to sheathe the heat pipe in a spacedly stacked manner. Each conic annular wall is embedded in each conic annular groove to be adapted to sheathe each slant inner annular wall in a compressive manner. Therefore, efficiency of heat dissipation and structural strength of the heat dissipation structure are improved.

### BACKGROUND OF THE DISCLOSURE

### Technical Field

The disclosure relates to a heat dissipation structure including a heat pipe and multiple heat dissipation fins, particularly to a heat dissipation structure and a manufacturing method thereof.

### Related Art

With the continuous increase of operating speed of electronic components, the generated heat is increasing accordingly. To solve the problem of high heat, the industry has developed various types of heat dissipation devices for heat dissipation. However, related-art heat dissipation devices still have drawbacks in practice.

A related-art heat dissipation device primarily includes a heat pipe, a thermo-conductive block and multiple heat dissipation fins. The heat pipe passes through both the thermo-conductive block and the heat dissipation fins. The thermo-conductive block is attached on an electronic component such as a central processing unit (CPU), so that the heat generated from the electronic component is dissipated to the outside through the heat dissipation fins and heat pipe.

In the process of inserting the heat pipe into the heat dissipation fins, however, the efficiency of heat dissipation and structural strength of the heat dissipation device are adversely affected if the heat dissipation fins cannot be firmly positioned on the heat pipe. Thus, how to firmly position the heat dissipation fins on the heat pipe is an important issue to be solved for the industry.

In view of this, the inventors have devoted themselves to the above-mentioned related art, researched intensively and cooperated with the application of science to try to solve the above-mentioned problems. Finally, the disclosure which is reasonable and effective to overcome the above drawbacks is provided.

### SUMMARY OF THE DISCLOSURE

The disclosure provides a heat dissipation structure and a manufacturing method thereof, which utilize each conic annular wall to be embedded in each conic annular groove to be adapted to sheathe each slant inner annular wall in a compressive manner. As a result, efficiency of heat dissipation and structural strength of the heat dissipation structure are improved.

In an embodiment of the disclosure, the disclosure provides a heat dissipation structure including a heat pipe and heat dissipation fins. The heat pipe has an outer annular wall with multiple conic annular grooves. A slant inner annular wall is disposed in each conic annular groove. Each heat dissipation fins has a through hole and a conic annular wall disposed on an outer edge of the through hole. The heat dissipation fins are adapted to sheathe the heat pipe in a spacedly stacked manner. Each conic annular wall is embedded in each conic annular groove to be adapted to sheathe each slant inner annular wall in a compressive manner.

In an embodiment of the disclosure, the disclosure provides a manufacturing method of a heat dissipation structure, which includes the steps of: a) providing a heat pipe, the heat pipe having an outer annular wall with multiple conic annular grooves, and a slant inner annular wall being disposed in each conic annular groove; b) providing multiple heat dissipation fins, each heat dissipation fin having a through hole and a conic annular wall formed on an outer edge of the through hole; and c) sheathing the heat pipe with the heat dissipation fins through the through holes until each conic annular wall being embedded to each conic annular groove and connected compressedly to each slant inner annular wall to make the heat dissipation fins be adapted to sheathe the heat pipe in a spacedly stacked manner.

Accordingly, the heat pipe is provided with multiple conic annular grooves, each heat dissipation fin has a conic annular wall, each conic annular wall is embedded in each conic annular groove to be adapted to sheathe each slant inner annular wall in a compressive manner, so that each conic annular wall is closely in thermal contact with each slant inner annular wall. This makes the heat of the heat pipe be rapidly transferred to the heat dissipation fins. The heat dissipation fins may also be firmly positioned on the heat pipe. Thus, efficiency of heat dissipation and structural strength of the heat dissipation structure may be improved.

### BRIEF DESCRIPTION OF THE DRAWINGS

FIG. 1 is a flowchart of the manufacturing method of the heat dissipation structure of the disclosure;

FIG. 2 is a perspective view of the disclosure, which shows the heat dissipation fins are being passed by the heat pipe;

FIG. 3 is a cross-sectional view of the disclosure, which shows the heat dissipation fins are being passed by the heat pipe;

FIG. 4 is a perspective view of the disclosure, which shows the heat dissipation fins have been passed by the heat pipe one by one;

FIG. 5 is a perspective view of the disclosure, which shows the heat dissipation fins have been passed by the heat pipe as an integral;

FIG. 6 is a cross-sectional view of the disclosure, which shows the conic annular walls are separately embedded into the conic annular grooves;

FIG. 7 is an enlarged view of the dotted-line frame in FIG. 6; and

FIG. 8 is a cross-sectional view of the disclosure, which shows the pressing mold is pressing the conic annular walls.

### DETAILED DESCRIPTION OF THE DISCLOSURE

To further disclose the features and technical contents of the disclosure, please refer to the following description and the drawings. However, the drawings are used for reference and description only, not for limitation to the disclosure.

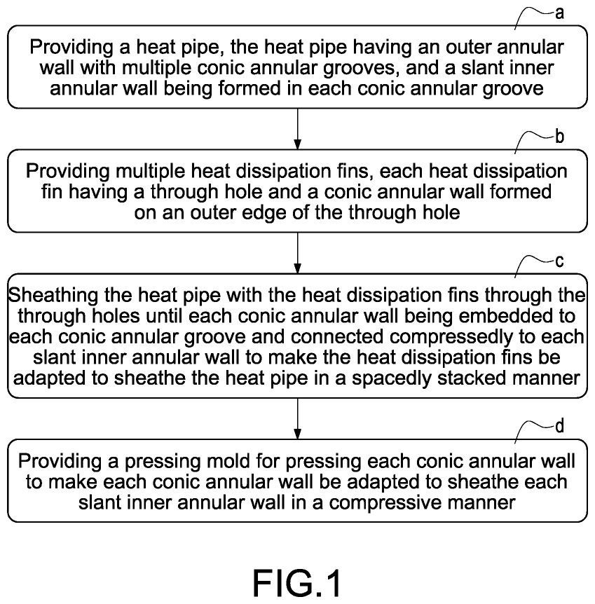

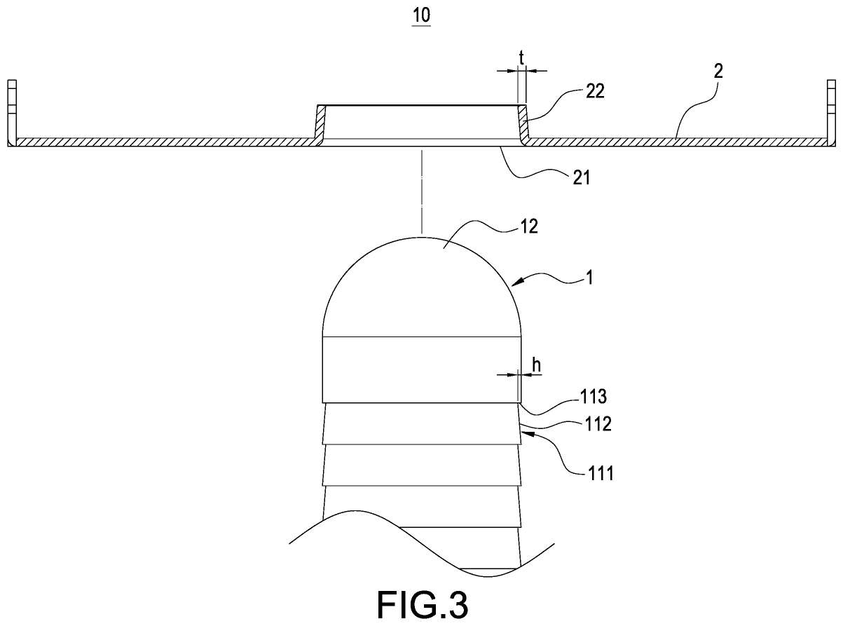

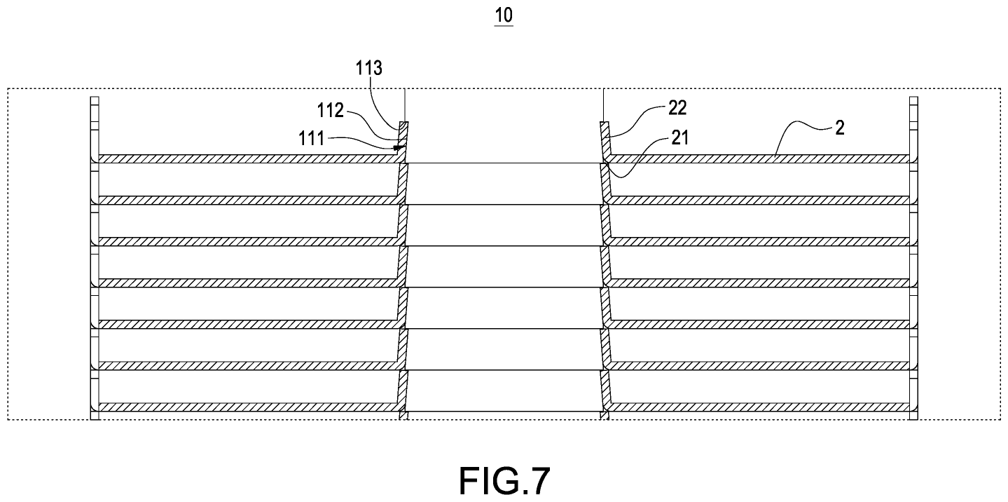

Please refer to FIGS. 1-8. The disclosure provides a heat dissipation structure and a manufacturing method thereof. The heat dissipation structure 10 includes one or more heat pipes 1 and a plurality of heat dissipation fins 2.

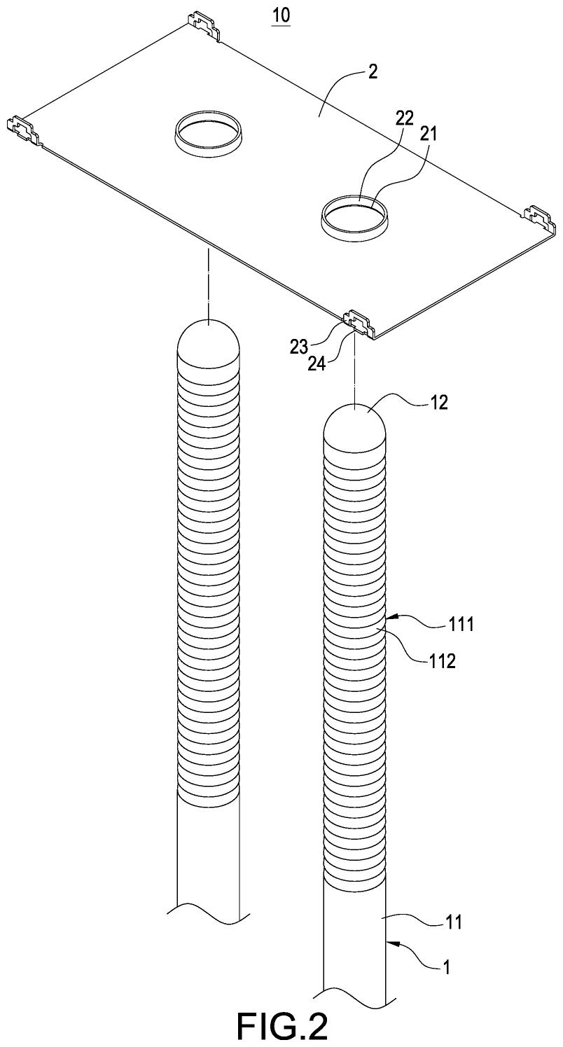

As shown in FIG. 1, this figure shows the steps of the manufacturing method of the heat dissipation structure. The details are described as follows. First, as shown in the step a) of FIG. 1 and FIG. 2, a heat pipe 1 is provided. The heat pipe 1 has an outer annular wall 11 with a plurality of conic annular grooves 111, and a slant inner annular wall 112 is disposed in each conic annular groove 111.

In addition, the heat pipe 1 has a top 12. Each of the slant inner annular walls 112 tapers toward the top 12 to be inclined inwardly. In the embodiment, the number of the heat pipe 1 is, but not limited to, multiple.

Secondly, as shown in the step b) of FIG. 1 and FIG. 2, a plurality of heat dissipation fins 2 are provided. Each heat dissipation fin 2 has a through hole 21 and a conic annular wall 22 disposed on an outer edge of the through hole 21. A number of the through hole 21 of each heat dissipation fin 2 is multiple, but not limited to this.

Besides, an inner diameter of each conic annular wall 22 is smaller than an outer diameter of each slant inner annular wall 112 by about 0.1 mm. For example, when an outer diameter of each slant inner annular wall 112 is 8 mm, an inner diameter of each conic annular wall 22 is about 7.9 mm, but not limited to this.

Thirdly, as shown in the step c) of FIG. 1 and FIGS. 2-7, the heat pipe 1 is sheathed with the heat dissipation fins 2 through the through holes 21 until each conic annular wall 22 is embedded in each conic annular groove 111 and connected compressedly to each slant inner annular wall 112 to make the heat dissipation fins 2 be adapted to sheathe the heat pipe in a spacedly stacked manner.

Furthermore, an outer periphery of each heat dissipation fin 2 is upwardly extended with a plurality of inverted T-shape connecting sheets 23 meshed with each other. The outer periphery of each heat dissipation fin 2 is outwardly extended with a plurality of latches 24 inserted respectively between each two of the inverted T-shape connecting sheets 23 adjacent to each other. This makes the heat dissipation fins 2 be firmly stacked and connected together.

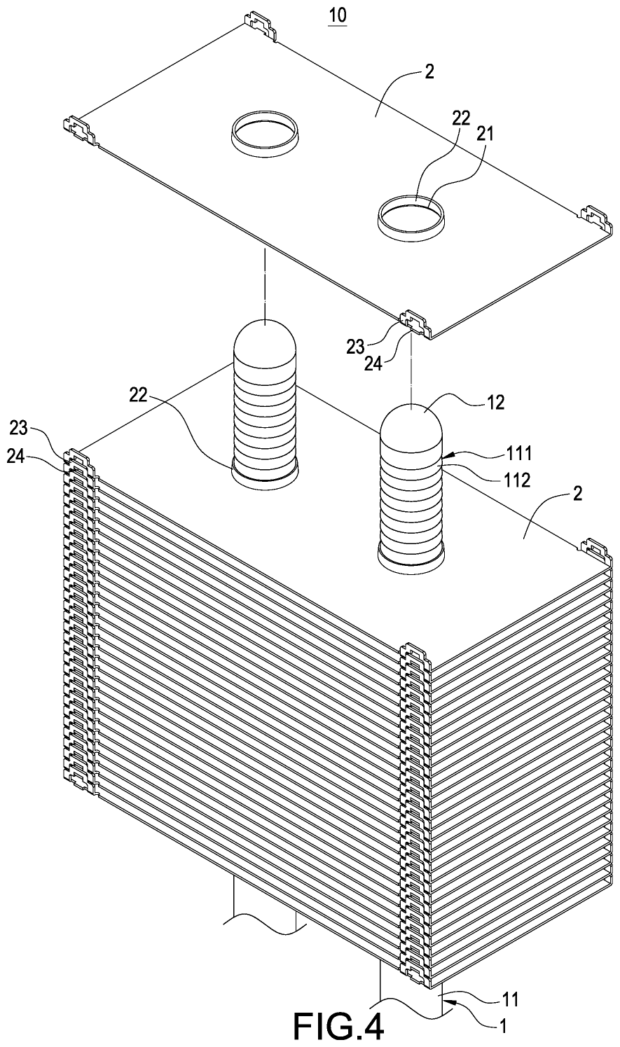

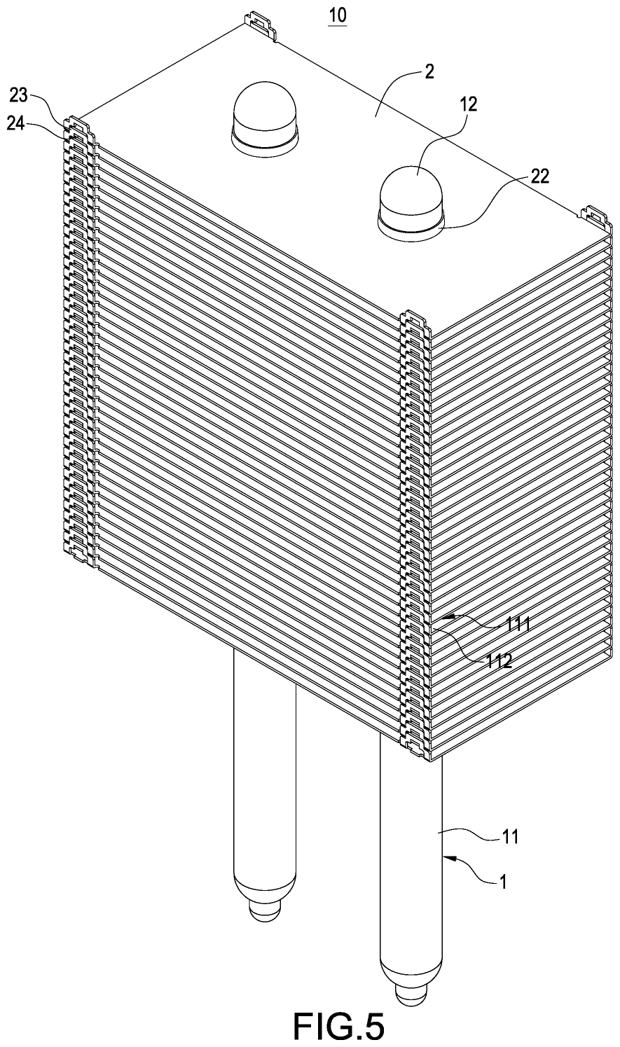

Also, as shown in FIG. 4, the heat dissipation fins 2 may be adapted to sheathe the heat pipe 1 in sequence from the top 12 of the heat pipe 1. As shown in FIG. 5, the heat dissipation fins 2 may also be adapted to sheathe the heat pipe 1 collectively from the top 12 of the heat pipe 1.

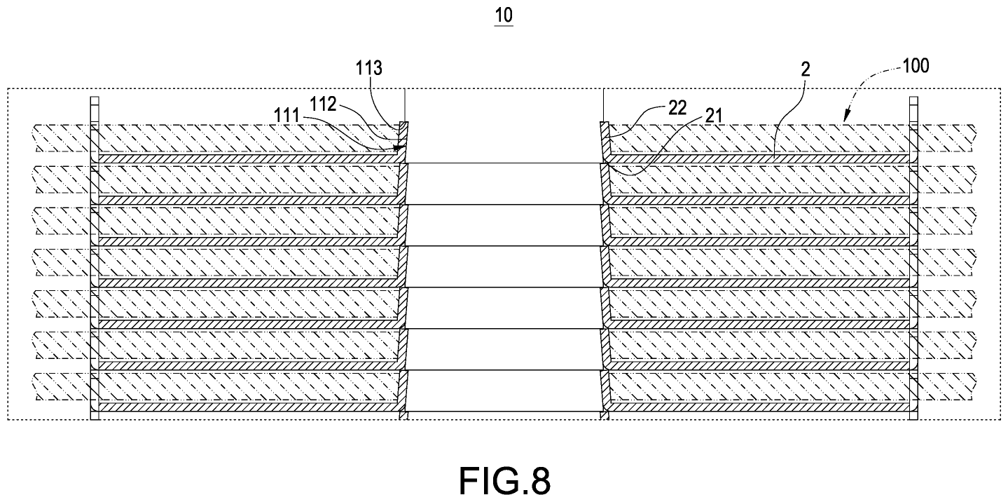

Fourthly, as shown in the step d) of FIG. 1 and FIG. 8, a pressing mold 100 is provided for pressing each conic annular wall 22 to make each conic annular wall 22 be adapted to sheathe each slant inner annular wall 112 in a compressive manner.

In the pressing process, the pressing mold 100 presses each conic annular wall 22 toward the heat pipe 1 to make a part of each conic annular wall 22 be embedded and connected compressedly to each annular sidewall 113.

In addition, an annular sidewall 113 is disposed in each conic annular groove 111 on a side of the slant inner annular wall 112 and adjacent to the top 12. A height h of each annular sidewall 113 is between ¼ and ½ of a thickness t of each conic annular wall 22, but not limited to this.

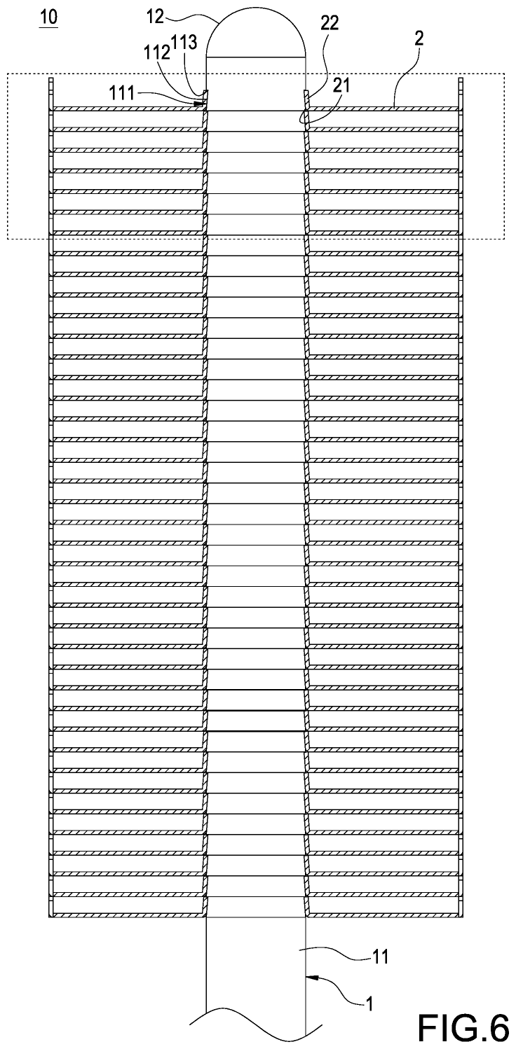

As shown in FIGS. 6-8, which show a using status of the heat dissipation structure 10 of the disclosure, the heat pipe 1 is provided with a plurality of conic annular grooves 111, each heat dissipation fin 2 has a conic annular wall 22, each conic annular wall 22 is embedded in each conic annular grooves 111 and adapted to sheathe each slant inner annular walls 112 in a compressive manner, so that each conic annular wall 22 is closely in thermal contact with each slant inner annular walls 112. This makes the heat of the heat pipe 1 be rapidly transferred to the heat dissipation fins 2. The heat dissipation fins 2 may also be firmly positioned on the heat pipe 1. Thus, efficiency of heat dissipation and structural strength of the heat dissipation structure 10 are improved.

Besides, the pressing mold 100 presses the conic annular walls 22 toward the heat pipe 1 to make a part of each conic annular wall 22 be securely embedded and connected compressedly to each annular sidewall 113. This further improves efficiency of heat dissipation and structural strength of the heat dissipation structure 10.

It will be appreciated by persons skilled in the art that the above embodiments have been described by way of example only and not in any limitative sense, and that various alterations and modifications are possible without departure from the scope of the disclosure as defined by the appended claims.

What is claimed is:

1. A heat dissipation structure comprising:
a heat pipe, comprising an outer annular wall with a plurality of conic annular grooves, and a slant inner annular wall disposed in each conic annular groove; and
a plurality of heat dissipation fins, each comprising a through hole and a conic annular wall disposed on an outer edge of the through hole, the heat dissipation fins adapted to sheathe the heat pipe in a spacedly stacked manner, and each conic annular wall embedded in each conic annular groove to be adapted to sheathe each slant inner annular wall in a compressive manner.

2. The heat dissipation structure of claim 1, wherein the heat pipe comprises a top, and each of the slant inner annular walls tapers toward the top to be inclined inwardly.

3. The heat dissipation structure of claim 2, wherein each conic annular groove comprises an annular sidewall disposed on a side of the slant inner annular wall and adjacent to the top, and a height of each annular sidewall is between ¼ and ½ of a thickness of each conic annular wall.

4. The heat dissipation structure of claim 1, wherein an outer periphery of each heat dissipation fin is upwardly extended with a plurality of inverted T-shape connecting sheets meshed with each other and is outwardly extended with a plurality of latches inserted respectively between each two of the inverted T-shape connecting sheets adjacent to each other.

5. A manufacturing method of a heat dissipation structure, the manufacturing method comprising:
a) providing a heat pipe comprising an outer annular wall with a plurality of conic annular grooves, and a slant inner annular wall being disposed in each conic annular groove;
b) providing a plurality of heat dissipation fins, each heat dissipation fin comprising a through hole and a conic annular wall formed at an outer edge of the through hole; and
c) sheathing the heat pipe with the heat dissipation fins through the through holes until each conic annular wall being embedded to each conic annular groove and connected compressedly to each slant inner annular wall to make the heat dissipation fins be adapted to sheathe the heat pipe in a spacedly stacked manner.

6. The method of claim 5, wherein in the step a), the heat pipe comprises a top, and each of the slant inner annular walls tapers toward the top to be inclined inwardly.

7. The method of claim 6, wherein in the step c), the heat dissipation fins are adapted to sheathe the heat pipe in sequence or collectively from the top of the heat pipe.

8. The method of claim 6, further comprising a step d) after the step c), the step d) comprising: providing a pressing mold for pressing each conic annular wall to make each conic annular wall be adapted to sheathe each slant inner annular wall in a compressive manner.

9. The method of claim 8, wherein in the step d), an annular sidewall is formed in each conic annular groove on a side of the slant inner annular wall and adjacent to the top, and a height of each annular sidewall is between ¼ and ½ of a thickness of each conic annular wall.

10. The method of claim 5, wherein in the step c), an outer periphery of each heat dissipation fin is upwardly extended with a plurality of inverted T-shape connecting sheets meshed with each other and is outwardly extended with a plurality of latches inserted respectively between each two of the inverted T-shape connecting sheets adjacent to each other.
